(19) United States
(12) Patent Application Publication
(10) Pub. No.: US 2009/0057802 A1
(43) Pub. Date: Mar. 5, 2009

(54) Image Sensor and Method for Manufacturing the Same

(76) Inventor: Jeong Su Park, Gwanak-gu (KR)

Correspondence Address: SALIWANCHIK LLOYD & SALIWANCHIK;A PROFESSIONAL ASSOCIATION, PO BOX 142950, GAINESVILLE, FL, 32614-2950, US

(21) Appl. No.: 12/200,112

(22) Filed: Aug. 28, 2008

(30) Foreign Application Priority Data
Aug. 30, 2007 (KR) 10-2007-0087551

(51) Int. Cl. H01L 31/102; H01L 21/265

(52) U.S. Cl. 257/440; 438/527; 257/E31.055; 257/E21.334

(57) ABSTRACT

Provided are an image sensor and a manufacturing method thereof. The image sensor can include a first epitaxial layer with a first ion implantation layer, a second epitaxial layer with a second ion implantation layer, and a third epitaxial layer with a third ion implantation layer on a substrate. The first, second, and third ion implantation layers can provide a red, green, and blue photodiode, respectively. A trench can be formed in the third epitaxial layer on the third ion implantation layer to remove the damaged surface of the third epitaxial layer.

### CROSS-REFERENCE TO RELATED APPLICATION

The present application claims the benefit under 35 U.S.C. §119 of Korean Patent Application No. 10-2007-0087551, filed Aug. 30, 2007, which is hereby incorporated by reference in its entirety.

### BACKGROUND

An image sensor is a semiconductor device for converting an optical image into an electrical signal. The image sensor is roughly classified as a charge coupled device (CCD) image sensor or a complementary metal oxide semiconductor (CMOS) image sensor (CIS).

The CIS includes photodiodes and MOS transistors arranged according to unit pixels, and sequentially detects electrical signals of respective unit pixels in a switching manner to realize an image.

The photodiode of an image sensor is typically formed by providing a silicon epitaxial layer on a semiconductor substrate, and then performing an ion implantation process with respect to the epitaxial layer.

For certain image sensors, the photodiode can be formed in three layers in the silicon epitaxial layer. These three layers can respectively accept red, green, and blue wave lengths.

### BRIEF SUMMARY

In one embodiment of the present invention, an image sensor is provided that comprises a first epitaxial layer, a second epitaxial layer, and a third epitaxial layer on a semiconductor substrate; a first ion implantation layer in the first epitaxial layer; a second ion implantation layer in the second epitaxial layer; a third ion implantation layer in the third epitaxial layer; and a trench in the third epitaxial layer on the third ion implantation layer.

In another embodiment, a method for manufacturing an image sensor can comprise: forming a first epitaxial layer on a semiconductor substrate; forming a first ion implantation layer in the first epitaxial layer; forming a second epitaxial layer on the first epitaxial layer in which the first ion implantation layer is formed; forming a second ion implantation layer in the second epitaxial layer; forming a third epitaxial layer on the second epitaxial layer in which the second ion implantation layer is formed; forming a third ion implantation layer in the third epitaxial layer; and forming a trench in the third epitaxial layer on the third ion implantation layer.

The details of one or more embodiments are set forth in the accompanying drawings and the description below. Other features will be apparent from the description and drawings, and from the claims.

### BRIEF DESCRIPTION OF THE DRAWINGS

FIGS. 1 to 8 are cross-sectional views of a manufacturing process of an image sensor according to an embodiment.

### DETAILED DESCRIPTION

Hereinafter, embodiments of an image sensor and a manufacturing method thereof are described in detail with reference to the accompanying drawings.

In the following description, it will be understood that when a layer (or film) is referred to as being ‘on/over’ another layer or substrate, it can be directly on the another layer or substrate, or intervening layers may also be present.

In the drawings, the thickness or size of each layer may be exaggerated, omitted, or schematically illustrated for convenience in description and clarity. Also, the size of each element does not entirely reflect an actual size.

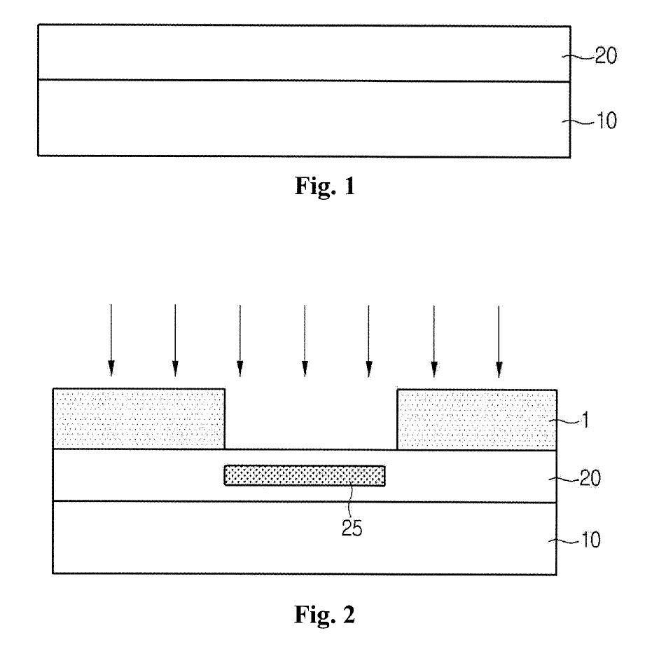

A manufacturing process of an image sensor according to an embodiment will be described with respect to FIGS. 1 to 8.

Referring to FIG. 1, a first epitaxial layer 20 can be formed on a semiconductor substrate 10.

The first epitaxial layer 20 can be formed to a thickness of, for example, about 3 μm by growing silicon using epitaxy equipment.

Referring to FIG. 2, first photoresist patterns 1 can be formed on the first epitaxial layer 20, and a first ion implantation process can be performed on the first epitaxial layer 20 to form a first ion implantation layer 25.

In a specific embodiment, the first ion implantation process can be performed by implanting arsenic (As) ions with a dose of about 1.0×10¹²˜1.0×10¹³ atoms/cm² at an energy of about 50-150 KeV.

The first ion implantation layer 25 can be used as a red photodiode.

After the first photoresist patterns 1 are removed, a first heat treatment process for activating the dopants implanted into the first ion implantation layer 25 can be performed.

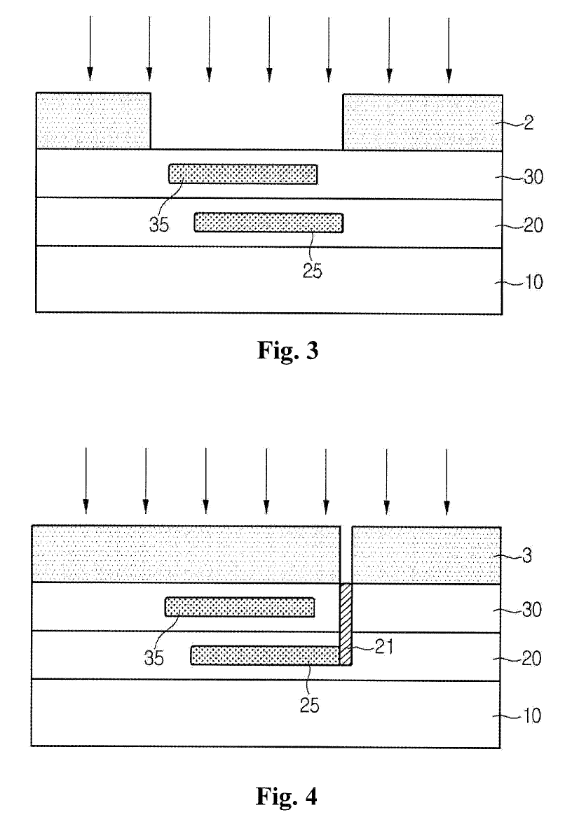

Subsequently, referring to FIG. 3, a second epitaxial layer 30 can be formed on the first epitaxial layer 20. Then, second photoresist patterns 2 can be formed on the second epitaxial layer 30, and a second ion implantation process can be performed to form a second ion implantation layer 35. The second photoresist pattern 2 can expose a region of the second epitaxial layer 30 that is offset from the first ion implantation layer 25.

The second epitaxial layer 30 can be formed to a thickness of, for example, about 2 μm by growing silicon using epitaxy equipment.

In a specific embodiment, the second ion implantation process can be performed by implanting As ions with a dose of about 1.0×10¹²˜1.0×10¹³ atoms/cm² at an energy of about 50-150 KeV.

The second ion implantation layer 35 can be used as a green photodiode.

After the second photoresist patterns 2 are removed, a second heat treatment process for activating the dopants implanted into the second ion implantation layer 35 can be performed.

Referring to FIG. 4, third photoresist patterns 3 can be formed on the second epitaxial layer 30, and a third ion implantation process can be performed to form a first contact 21 connecting to the first ion implantation layer 25.

The third ion implantation process can be performed by implanting As ions into the second epitaxial layer 30 and the first epitaxial layer 20 to contact the first ion implantation layer 25.

The first contact 21 is formed to connect with a device such as a transistor for transferring and processing a signal generated by the red photodiode.

The third photoresist patterns 3 can be removed and a third heat treatment process for activating the dopants implanted into the first contact 21 can be performed.

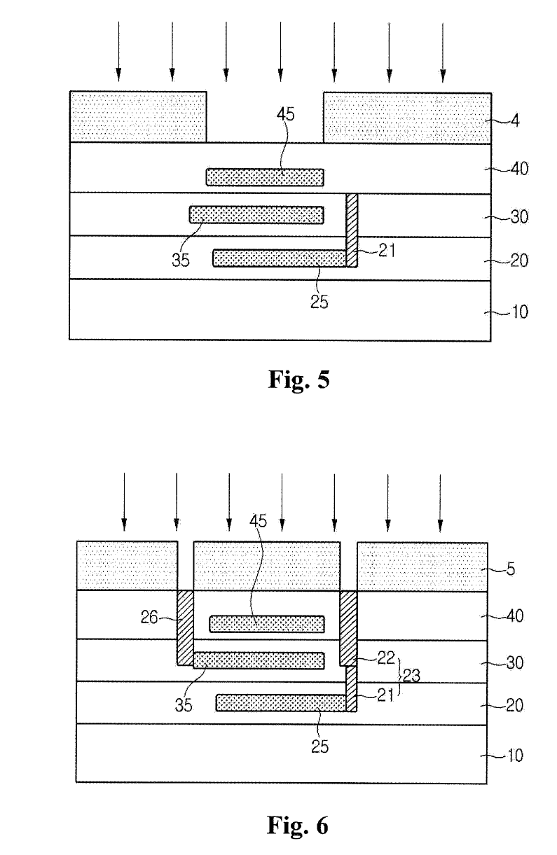

Referring to FIG. 5, a third epitaxial layer 40 can be formed on the second epitaxial layer 30. Fourth photoresist patterns 4 can be formed on the third epitaxial layer 40, and a fourth ion implantation process can be performed to form a third ion implantation layer 45. The fourth photoresist patterns 4 can expose a region of the third epitaxial layer 40 that is directly aligned with, but does not completely overlap the second ion implantation layer 35.

The third epitaxial layer 40 can be formed to a thickness of, for example, about 1.5-2.0 μm by growing silicon using epitaxy equipment.

In a specific embodiment, the fourth ion implantation process can be performed by implanting As ions with a dose of about 1.0×10¹²˜1.0×10¹³ atoms/cm² at an energy of about 50-150 KeV.

The third ion implantation layer 45 can be used as a blue photodiode.

After the fourth photoresist patterns 4 are removed, a fourth heat treatment process for activating the dopants implanted into the third ion implantation layer 45 can be performed.

Referring to FIG. 6, fifth photoresist patterns 5 can be formed on the third epitaxial layer 40, and a fifth ion implantation process can be performed to form a second contact 22 connected to the first contact 21 and a third contact 26 connected to the second implantation layer 35.

The fifth ion implantation process can be performed by implanting As ions into the third epitaxial layer 40 and the second epitaxial layer 30. The second contact 22 and the third contact 26 can be simultaneously formed.

The first contact 21 and the second contact 22 are connected with each other to form a fifth contact 23 for connecting with the device for transferring and processing the signal generated by the red photodiode.

The third contact 26 is formed to connect with a device such as a transistor for transferring and processing a signal generated by the green photodiode.

After the fifth photoresist patterns 5 are removed, a fifth heat treatment process for activating the dopants implanted to form the second contact 22 and the third contact 23 can be performed.

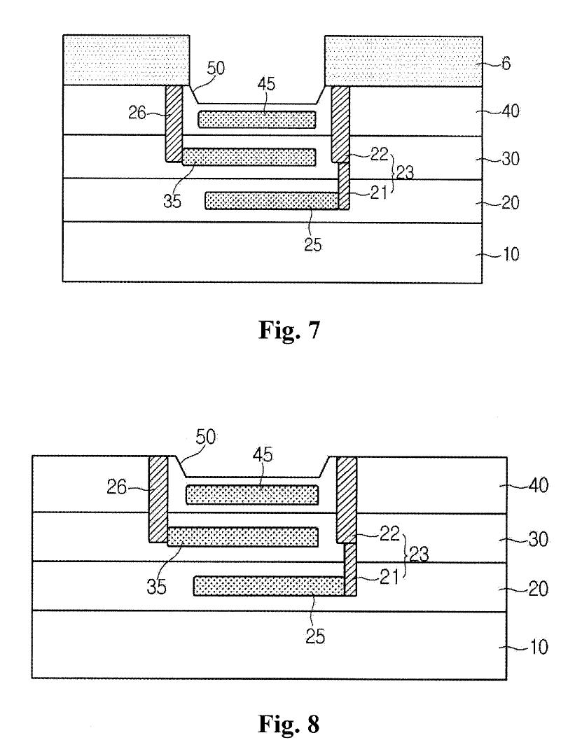

Subsequently, referring to FIG. 7, sixth photoresist patterns 6 can be formed on the third epitaxial layer 40, and a dry etching process can be performed to form a trench 50 in the third epitaxial layer 40 on the third ion implantation layer 45.

The dry etching process can be performed with consideration of a silicon etch rate depending on a time.

The trench 50 is formed in order to remove a damaged surface of the third epitaxial layer 40. The surface of the third epitaxial layer 40 may be damaged during the fourth ion implantation process for forming the third ion implantation layer 45 in the region for the blue photodiode.

Since the surface damage by the ion implantation process causes a leakage current, a defect may be generated in the device.

At this point, according to embodiments, the second epitaxial layer 30 is located on the first epitaxial layer 20 in which the first ion implantation layer 25 has been formed, and the third epitaxial layer 40 is formed on the second epitaxial layer 30 in which the second ion implantation layer 35 has been formed, so that damage by the ion implantation process for the first ion implantation layer 25 and the second ion implantation layer 35 is recovered by the epitaxial layer formation, and thus a leakage current is reduced.

That is, since damage is generated to only the surface of the third epitaxial layer 40 on which an additional epitaxial layer is not formed, the focus can be on the surface of the third epitaxial layer 40. Accordingly, the third epitaxial layer 40 can be formed to a thickness of about 1.5-2.0 μm, and the trench 50 is then formed using an etching process, so that the damaged surface of the third epitaxial layer 40 is removed. Thus, generation of a leakage current can be further reduced.

As shown in FIG. 8, after the photoresist patterns 6 are removed, the red, green, and blue photodiodes where the first, second, and third ion implantation layers 25, 35, and 45 are formed can be provided.

The red, green, and blue photodiodes are vertically arranged in one pixel, so that high quality image can be realized and various colors can be realized without a separate color filter process.

Also, though not shown, after the red, green, and blue photodiodes are formed, a device isolation layer can be formed in the semiconductor substrate 10 including the first, second, and third epitaxial layers 20, 30, and 40, and transistors that can transfer and process various signals can be formed.

Also, after the device isolation layer and the transistor are formed, an interlayer dielectric, metal interconnections, and microlenses can be formed on the semiconductor substrate 10 including the first, second, and third epitaxial layers 20, 30, and 40.

FIG. 8 is a cross-sectional view of a photodiode region of an image sensor according to an embodiment.

The image sensor according to an embodiment includes: a first epitaxial layer 20, a second epitaxial layer 30, and a third epitaxial layer 40 on a semiconductor substrate 10; a first ion implantation layer 25 in the first epitaxial layer 20; a second ion implantation layer 35 in the second epitaxial layer 30; a third ion implantation layer 45 in the third epitaxial layer 40; and a trench 50 in the third epitaxial layer 40 on the third ion implantation layer 45.

The first ion implantation layer 25 can be used as a red photodiode, the second ion implantation layer 35 can be used as a green photodiode, and the third ion implantation layer 45 can be used as a blue photodiode.

According to embodiments, the third epitaxial layer 40 can be formed to a thickness of about 1.5-2.0 μm, and the trench 50 can be formed to a depth of about 0.3-0.7 μm.

A contact 23 can be formed connected with the first ion implantation layer 25; and another contact 26 can be formed connected with the second ion implantation layer 35.

As described above, in the image sensor and the manufacturing method thereof according to embodiments, the epitaxial layer for forming the blue photodiode is formed, and the trench is then formed using an etching process, so that the damaged surface of the epitaxial layer is removed and thus generation of a leakage current can be inhibited.

Any reference in this specification to “one embodiment,” “an embodiment,” “example embodiment,” etc., means that a particular feature, structure, or characteristic described in connection with the embodiment is included in at least one embodiment of the invention. The appearances of such phrases in various places in the specification are not necessarily all referring to the same embodiment. Further, when a particular feature, structure, or characteristic is described in connection with any embodiment, it is submitted that it is within the purview of one skilled in the art to effect such feature, structure, or characteristic in connection with other ones of the embodiments.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. An image sensor comprising:
a first epitaxial layer on a semiconductor substrate;
a second epitaxial layer on the first epitaxial layer;
a third epitaxial layer on the second epitaxial layer;
a first ion implantation layer in the first epitaxial layer;
a second ion implantation layer in the second epitaxial layer;
a third ion implantation layer in the third epitaxial layer; and
a trench in the third epitaxial layer on the third ion implantation layer.

2. The image sensor according to claim 1, wherein the first ion implantation layer provides a red photodiode, the second ion implantation layer provides a green photodiode, and the third ion implantation layer provides a blue photodiode.

3. The image sensor according to claim 1, wherein the third epitaxial layer has a thickness of about 1.5-2.0 μm, and the trench has a depth of about 0.3-0.7 μm.

4. The image sensor according to claim 1, further comprising:
a first contact connected with the first ion implantation layer; and
a second contact connected with the second ion implantation layer.

5. The image sensor according to claim 4, wherein the first contact comprises a fourth ion implanted region passing through the third epitaxial layer, the second epitaxial layer, and a portion of the first epitaxial layer to contact the first ion implantation layer; and
wherein the second contact comprises a fifth ion implanted region passing through the third epitaxial layer and a portion of the second epitaxial layer to contact the second ion implantation layer.

6. A method for manufacturing an image sensor, comprising:
forming a first epitaxial layer on a semiconductor substrate;
forming a first ion implantation layer in the first epitaxial layer;
forming a second epitaxial layer on the first epitaxial layer in which the first ion implantation layer is formed;
forming a second ion implantation layer in the second epitaxial layer;
forming a third epitaxial layer on the second epitaxial layer in which the second ion implantation layer is formed;
forming a third ion implantation layer in the third epitaxial layer; and
forming a trench in the third epitaxial layer on the third ion implantation layer.

7. The method according to claim 6, wherein the first ion implantation layer provides a red photodiode, the second ion implantation layer provides a green photodiode, and the third ion implantation layer provides a blue photodiode.

8. The method according to claim 6, wherein the third epitaxial layer is formed to a thickness of about 1.5-2.0 μm, and the trench is formed to a depth of about 0.3-0.7 μm.

9. The method according to claim 6, further comprising:
forming a first contact passing through the second epitaxial layer and a portion of the first epitaxial layer and connected with the first ion implantation layer, after the forming of the second ion implantation layer; and
forming a second contact passing through the third epitaxial layer and a portion of the second epitaxial layer, and connected with the first contact, after the forming of the third ion implantation layer.

10. The method according to claim 9, further comprising forming a third contact passing through the third epitaxial layer and a portion of the second epitaxial layer, and connected with the second ion implantation layer, after the forming of the third ion implantation layer.

11. The method according to claim 10, wherein the second contact and the third contact are simultaneously formed.

12. The method according to claim 10, wherein forming the first, second, and third contacts comprises performing ion implantation processes.

13. The method according to claim 6, wherein the first, second, and third ion implantation layers are each formed by implanting As ions with a dose of about 1.0×10¹²˜1.0×10¹³ atoms/cm² at an implantation energy of about 50-150 KeV.

14. The method according to claim 6, further comprising:
performing a first heat treatment process on the semiconductor substrate after the forming of the first ion implantation layer;
performing a second heat treatment process on the semiconductor substrate after the forming of the second ion implantation layer; and
performing a third heat treatment process on the semiconductor layer after the forming of the third ion implantation layer.
